(19) United States
(12) Patent Application Publication
(10) Pub. No.: US 2018/0023552 A1
(43) Pub. Date: Jan. 25, 2018

(54) MICROFLUIDIC OSCILLATOR PUMP

(71) Applicants: Elliot En-Yu Hui, South Pasadena, CA (US); Philip N. Duncan, Fullerton, CA (US); Transon V. Nguyen, Cambridge, MA (US)

(72) Inventors: Elliot En-Yu Hui, South Pasadena, CA (US); Philip N. Duncan, Fullerton, CA (US); Transon V. Nguyen, Cambridge, MA (US)

(21) Appl. No.: 15/711,946

(22) Filed: Sep. 21, 2017

Related U.S. Application Data
(63) Continuation-in-part of application No. 14/029,286, filed on Sep. 17, 2013, now Pat. No. 9,784,258.
(60) Provisional application No. 61/813,099, filed on Apr. 17, 2013.
(60) Provisional application No. 61/702,709, filed on Sep. 18, 2012.

(51) Int. Cl. F04B 19/00; F04B 53/10; F16K 99/00; F04B 9/12

(52) U.S. Cl. CPC F04B 19/006; F04B 9/1207; F04B 53/10; F16K 99/0055; F16K 99/0015; H03K 3/0315

(57) ABSTRACT

Microfluidic oscillator circuits and pumps for microfluidic devices are provided. The microfluidic pump may include a plurality of fluid valves and a microfluidic oscillator circuit having an oscillation frequency. The fluid valves may be configured to move fluids. Each fluid valve may be connected to a node of the microfluidic oscillator circuit. The pumps may be driven by the oscillator circuits such that fluid movement is accomplished entirely by circuits on a microfluidic chip, without the need for off-chip controls.

### CROSS REFERENCE

This application claims benefit to and is a continuation-in-part of U.S. Non-Provisional application Ser. No. 14/029,286 filed Sep. 17, 2013, which claims benefit to U.S. Provisional Applications 61/702,709 filed Sep. 18, 2012 and 61/813,099 filed Apr. 17, 2013, the specifications of which are incorporated herein by reference in their entirety.

### GOVERNMENT SUPPORT

This invention was made with government support under Grant No. ECCS-1102397 awarded by the National Science Foundation and under Grant No. N66001-10-1-4003 awarded by the Defense Advanced Research Projects Agency. The government has certain rights in the invention.

### FIELD OF THE INVENTION

The present invention relates to microfluidic structures, more specifically, microfluidic oscillator circuits and pumps for microfluidic devices are provided.

### BACKGROUND OF THE INVENTION

The present invention relates to microfluidic devices. The integration of laboratory operations on a microfluidic device has numerous applications in medical diagnostics and biological science. Research into microfluidic devices, which perform various functions for biochemical reactions using biochemical fluids, such as blood, urine, saliva and sputum, for example, and detect the results thereof, has been actively pursued. Microfluidic devices may be of a chip type such as a lab-on-a-chip or of disk type such as a lab-on-a-disk. The lab-on-a-chip and lab-on-a-disk have received much attention in chemical and biotechnology fields since such devices may increase reaction rates, be automated, be made portable, and use a small amount of reagent. A microfluidic device typically includes a microchannel, through which a fluid flows, and a microvalve, which controls the flow of fluid in the microchannel. In a microfluidic device, the microvalve or microvalves control the transfer, mixing, accurate metering, biochemical reaction, isolation and detection of a sample in the microfluidic device of a chip type such as a lab-on-a-chip.

A variety of liquid handling operations can be performed using microfluidics technology, thus allowing complex laboratory assays to be automated on a compact chip. Integrated microfluidics is a technology that allows valves and pumps to be built right on the microfluidics chip, thus allowing complex liquid handling and a high degree of multiplexing. In order to execute the required liquid handling operations, the valves and pumps on the chip must be activated at the proper time. Typically, this is achieved by computer controlled pneumatic actuators that sit outside of the chip itself and are connected to the chip through a network of tubing. While this has worked well in engineering laboratories, the considerable amount of off-chip machinery is too cumbersome and complex for general use. The need for off-chip controls introduces significant disadvantages in terms of size, cost, ease of use, and reliability. The implementation of digital logic circuits out of microfluidic valves and channels could potentially enable fully self-contained systems that are controlled by onboard circuitry, thus eliminating the need for off-chip controls.

Any feature or combination of features described herein are included within the scope of the present invention provided that the features included in any such combination are not mutually inconsistent as will be apparent from the context, this specification, and the knowledge of one of ordinary skill in the art. Additional advantages and aspects of the present invention are apparent in the following detailed description and claims.

### SUMMARY OF THE INVENTION

The present invention features a microfluidic pump, comprising a ring oscillator circuit, configured to mix, meter, recirculate, or agitate gases or liquids. In some embodiments the microfluidic pump comprises a ring oscillator circuit that produces a plurality of pressure oscillations for driving a plurality of out-of-phase expansions and contractions of a plurality of valves arranged in series. In further embodiments, two or more of the pressure oscillations are phase shifted relative to one another by a value not equal to 180 degrees to create asymmetry. This asymmetric phase shift enables the out-of-phase expansions and contractions of the plurality of valves to drive the net transport of a gas or liquid.

In additional embodiments, the ring oscillator circuit further comprises an odd number of three or more pneumatic or hydraulic inverter logic gates, hereinafter referred to as inverter logic gates, and one or more logic channels routing the flow of the gas or liquid. The inverter logic gates may be connected in series to form a ring, such that the output of each inverter logic gate is operatively connected by a logic channel to the input of the next inverter logic gate. The output of the last inverter logic gate may then be operatively connected to the input of the first inverter logic gate.

In other embodiments, the plurality of valves sequentially connects the plurality of fluid channels. Each valve may be operatively connected to the output of one of the inverter logic gates via a node. In one embodiment, each node is disposed at the output of each inverter logic gate. In an alternate embodiment, a single node is disposed between each pair of consecutive inverter logic gates.

In supplementary embodiments, the ring oscillator circuit comprises three inverter logic gates while the pump comprises three valves. In an alternate embodiment, the ring oscillator circuit may comprise five inverter logic gates while the pump comprises three valves.

In additional embodiments, the inverter logic gates are powered by a pressure differential, where low pressure is defined as ground. In some embodiments, an application of high pressure at the input of an inverter logic gate results in low pressure at the output of said inverter logic gate. Further, an application of low pressure at the input of the inverter logic gate results in high pressure at the output of said inverter logic gate. In other embodiments, each valve is configured to be open at an application of high pressure at the output of the inverter logic gate to which said valve is connected and closed at an application of low pressure at the output of the inverter logic gate to which said valve is connected.

In an alternate embodiment, each pneumatic inverter logic gate is driven by vacuum pressure, via a vacuum supply source, and exhibits a gain greater than 1. In some embodiments, the vacuum supply source is a syringe. In other embodiments, atmospheric pressure is defined as ground. In this configuration, an application of vacuum pressure at the input of a pneumatic inverter logic gate results in atmospheric pressure at the output of said pneumatic inverter logic gate. Moreover, an application of atmospheric pressure at the input of the pneumatic inverter logic gate results in vacuum pressure at the output of the pneumatic inverter logic gate. Each valve may be configured to be open at an application of vacuum pressure to the output of an associated pneumatic inverter logic gate. Each valve may close at an application of atmospheric pressure to the output of the associated pneumatic inverter logic gate. In these embodiments, the ring oscillator circuit exhibits an oscillation frequency that varies as a function of the gain characteristics of the pneumatic inverter logic gates.

Various microfluidic structures implementing fluid logic have been proposed and are the subject of prior patents. For instance, Devaraju (US 2013/0255799) discloses a microfluidic device having an input source, input channel, output channel, a normally closed valve, and a control channel. The open state of the valve is associated with a source pressure greater than or equal to the sum of the control pressure and the static pressure. Enabled embodiments disclosed by Devaraju feature a microfluidic, device driven by positive pressure. The present invention is in stark contrast to the Devaraju invention because the ring oscillator circuit of the present invention is driven by vacuum pressure. The application of vacuum pressure provides a high non-linear gain, which is critical for noise suppression in digital systems and allows for fan-out and cascading. Typically, additional engineering is required in order to achieve a gain in positive pressure driven pneumatic and hydraulic approaches, as is the case for the Devaraju invention.

Mathies (US 2007/0237686) discloses a microfluidic device having at least three membrane valves each including a valve input, valve output, valve control, and an elastomer membrane configured to deflect in order to modulate the flow of a fluid through the associated valve at an application of pressure or a vacuum. Mathies' microfluidic device fails to teach the ring oscillator circuit (comprising an odd number of three or more inverter logic gates connected, via a plurality of fluid channels, in series to form a ring) of the present invention. The ring oscillator circuit is critical because it provides a plurality of pressure oscillations that drive a plurality of out-of-phase expansions and contractions of each fluid channel. Two or more of these pressure oscillations are asymmetrically phase-shifted relative to one another. Here, an asymmetric phase shift is defined as a shift in phase of one oscillation relative to another oscillation, where the shift in phase is not 180 degrees. This asymmetric, out-of-phase expansion and contraction of he plurality of fluid channels is what drives the net transport of the gas or liquid.

Nakayama (U.S. Pat. No. 5,247,208) discloses a substrate bias generating circuit comprising an electrical ring oscillator providing two signals, having a large phase difference, to two charge pump circuits. Though Nakayama's invention is an electrical device, its implementation with microfluidic devices would still fail to yield the present invention. Nakayama employs a signal shaping circuit for shaping the waveforms of the two signals such that the first signal is high when the second signal is low, and vice versa; which translates to a 180 degree phase shift between the two signals. This symmetry of waveforms (i.e. the 180 degree phase shift between signals), is different from the present invention as the present invention employs waveforms having an asymmetric phase-shift, i.e. not equal to 180 degrees. The Nakayama prior art teaches away from the asymmetry of waveforms and seeks to reduce the occurrence of a period where the two signals have the same value, particularly a low value. However, the present invention is designed to incorporate these periods of overlap in order to provide a delay to the valves so that as one valve opens another valve is not immediately closed. This design allows for a determined direction of flow of the fluid.

As such, the microfluidic device of Nakayama's design would be ineffective for pumping a fluid. This configuration would create a valve actuation pattern that is perfectly symmetric with respect to the two ports of the pump. Thus, there can be no net pumping of fluid, as it is not possible to determine which port is the pump entrance and which is the pump exit due to the symmetry.

### BRIEF DESCRIPTION OF THE DRAWINGS

The features and advantages of the present invention will become apparent from a consideration of the following detailed description presented in connection with the accompanying drawings in which:

FIG. 1 shows a diagrammatic representation of a 3-inverter oscillator circuit.

FIG. 2 shows a diagrammatic representation of an oscillator pump, including a three-inverter ring oscillator circuit coupled with three in-line fluid valves for peristaltic pumping of fluids from a fluid inlet through the three fluid valves to a fluid outlet.

FIG. 3 shows a graphical representation of the output values at nodes 1, 2, and 3 of FIG. 2 and a graphical and diagrammatic representation of the opening and closing of valves A, B, and C of FIG. 2 as a function of time.

FIG. 4 shows a diagrammatic view of a pneumatic membrane valve.

FIG. 5 shows an alternate diagrammatic view of a pneumatic membrane valve.

FIG. 6 shows a diagrammatic representation of a pneumatic inverter logic gate and an electronic inverter logic gate using an n-channel field effect transistor.

### DETAILED DESCRIPTION OF THE INVENTION

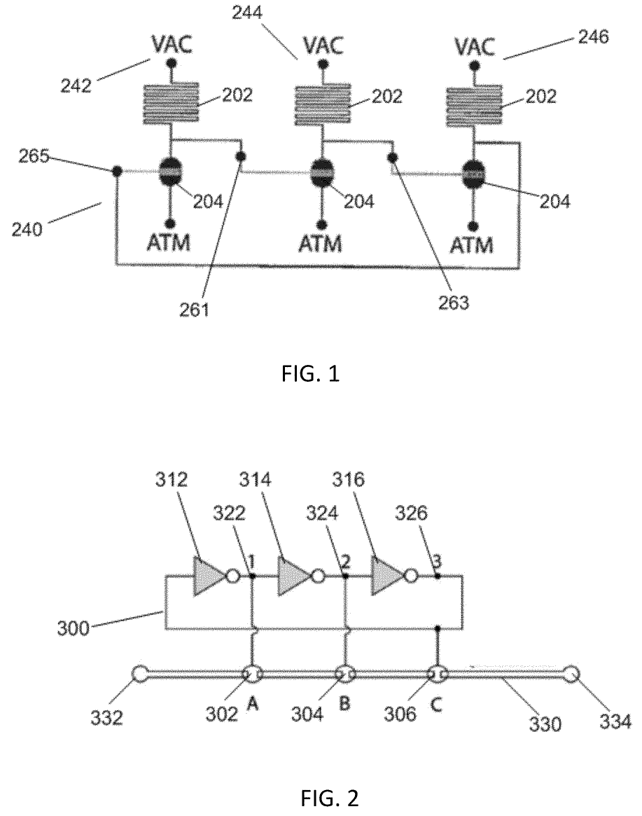

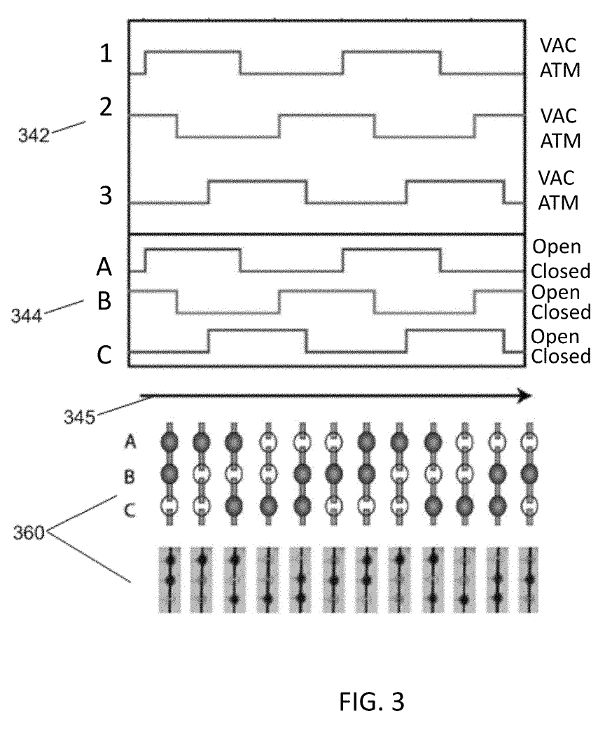

Referring now to FIGS. 1-6, some embodiments of the present invention feature a microfluidic pump (400) comprising a ring oscillator circuit (350) that produces a plurality of pressure oscillations for driving a plurality of out-of-phase expansions and contractions of a plurality of valves (302,304,306) arranged in series. In further embodiments, two or more of the pressure oscillations are phase shifted relative to one another by a value not equal to 180 degrees to create asymmetry. This asymmetric phase shift enables the out-of-phase expansions and contractions of the plurality of valves (302,304,306) to drive the net transport of a gas or liquid. In one embodiment, the two or more pressure oscillations have an asymmetric phase shift of 60 degrees. In a preferred embodiment, the two or more pressure oscillations have an asymmetric phase shift of 72 degrees.

The pump (400) may be configured to mix, meter, recirculate, or agitate gases or liquids. In additional embodiments, the ring oscillator circuit (350) further comprises an odd number of three or more inverter logic gates (312,314,316) and one or more logic channels (300) routing the flow of the gas or liquid. The inverter logic gates (312,314,316) may be connected in series to form a ring, such that the output of each inverter logic gate is operatively connected by a logic channel to the input of the next inverter logic gate. The output of the last inverter logic gate may then be operatively connected to the input of the first inverter logic gate.

In other embodiments, the plurality of valves (302,304,306) sequentially connects the plurality of fluid channels (330). Each valve may be operatively connected to the output of one of the inverter logic gates (312,314,316) via a node (322,324,326). In one embodiment, each node is disposed at the output of each inverter logic gate. In an alternate embodiment, a single node is disposed between each pair of consecutive inverter logic gates.

In supplementary embodiments, the ring oscillator circuit (350) comprises three inverter logic gates while the pump (400) comprises three valves. In an alternate embodiment, the ring oscillator circuit (350) may comprise five inverter logic gates while the pump (400) comprises three valves.

In yet other embodiments, the ring oscillator circuit (350) comprises one inverter logic gate while the pump (400) comprises a first valve and a second valve. In these embodiments, the first valve is operatively connected to the output of the inverter logic gate via an output node and the second valve is operatively connected to the input of the inverter logic gate via an input node. Further, the one or more logic channels (300) may operatively connect the input and the output of the inverter logic gate to form a ring configuration. Additionally, the first and the second valve may sequentially connect the plurality of fluid channels (330). Moreover, the fluidic resistance of the one or more logic channels (300) results in a phase shift between oscillations at the input and output nodes, said oscillations results in the plurality of pressure oscillations driving the plurality of out-of-phase expansions and contractions of the first and the second valves.

In additional embodiments, the inverter logic gates (312,314,316) are powered by a pressure differential, where low pressure is defined as ground. In some embodiments, an application of high pressure at the input of an inverter logic gate results in low pressure at the output of said inverter logic gate. Further, an application of low pressure at the input of the inverter logic gate results in high pressure at the output of said inverter logic gate. In other embodiments, each valve (302,304,306) is configured to be open at an application of high pressure at the output of the inverter logic gate to which said valve is connected and closed at an application of low pressure at the output of the inverter logic gate to which said valve is connected.

In an alternate embodiment, each pneumatic inverter logic gate is driven by vacuum pressure, via a vacuum supply source, and exhibits a gain greater than 1. In some embodiments, the vacuum supply source is a syringe. In other embodiments, atmospheric pressure is defined as ground. In this configuration, an application of vacuum pressure at the input of a pneumatic inverter logic gate results in atmospheric pressure at the output of said pneumatic inverter logic gate. Moreover, an application of atmospheric pressure at the input of the pneumatic inverter logic gate results in vacuum pressure at the output of the pneumatic inverter logic gate. Each valve (302.304,306) may be configured to be open at an application of vacuum pressure to the output of an associated pneumatic inverter logic gate. Each valve (302,304,306) may close at an application of atmospheric pressure to the output of the associated pneumatic inverter logic gate. In these embodiments, the ring oscillator circuit (350) exhibits an oscillation frequency that varies as a function of the gain characteristics of the pneumatic inverter logic gates.

In an embodiment, the ring oscillator circuit (350) is treated by a thermal annealing process to improve the stability of the oscillation frequency.

In further embodiments, each pneumatic inverter logic gate comprises: a pneumatic membrane valve having a membrane valve control channel, a membrane valve input channel, and a membrane valve output channel. When vacuum pressure is applied to the membrane valve control channel, the pneumatic membrane valve opens allowing the atmospheric pressure to flow from the membrane valve input channel to the membrane valve output channel, thus closing the plurality of valves (302.304,306). Moreover, when atmospheric pressure is applied to the membrane valve control channel, the pneumatic membrane valve closes allowing vacuum pressure to flow from the membrane valve input channel to the membrane valve output channel, thus opening the plurality of valves (302,304,306).

The gain exhibited by the pneumatic inverter logic gates is highly non-linear and critical for noise suppression in digital systems and allows for fan-out and cascading. It is likely that gain occurs because the adhesion of the membrane to the valve seat dominates over the mechanical elasticity of the membrane, thus causing the valve to remain fully closed below a threshold pressure and to snap fully open quickly once that threshold is exceeded and adhesion is broken. Importantly, this intrinsic non-linear gain is not present in pressure-driven pneumatic and hydraulic approaches. Instead, additional engineering has been required in order to achieve gain in these other logic technologies. Additionally, pneumatic logic is advantageous over hydraulic logic due to the two orders-of-magnitude difference in viscosity between water and air, resulting in a significant inherent speed advantage for pneumatics.

In other embodiments, each pneumatic inverter logic gate further comprises a pull-up resistor channel. The pull-up resistor channel may comprise a long narrow channel separating the vacuum supply source from the output of the pneumatic membrane valve. A pull-up resistance characterizes each pull-up resistor channel and varies as a function of the length of the long narrow channel. Further, the oscillation frequency of the ring oscillator circuit (350) may vary as a function of the resistance characteristics of the pull-up resistor channel.

### Details of the Microfluidic Pump of the Present Invention

It should be noted that the fluid control structures suitable for use in microfluidic devices can be applied to a variety of microfluidic devices. A pathogen detection system is a good example of one possible application that can benefit from the use of fluid control structures. Also, it should be noted that a fluid is considered to be an aggregate of matter in which the molecules are able to flow past each other, such as a liquid, gas or combination thereof, without limit and without fracture planes forming. Moreover, while references may primarily be made to pneumatic implementations of the claimed invention, it should be noted that the claimed invention may be implemented using a hydraulic microfluidic circuit. In the following description, numerous specific details are set forth in order to provide a thorough understanding of the present invention. The present invention may be practiced without some or all of these specific details. In other instances, well known operations have not been described in detail in order not to unnecessarily obscure the present invention.

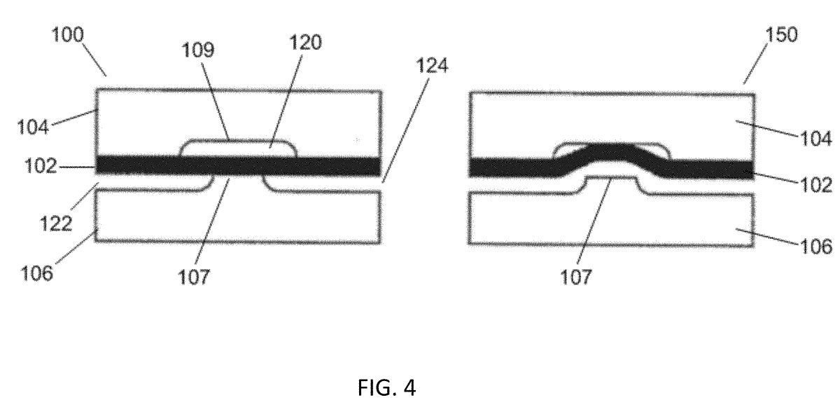

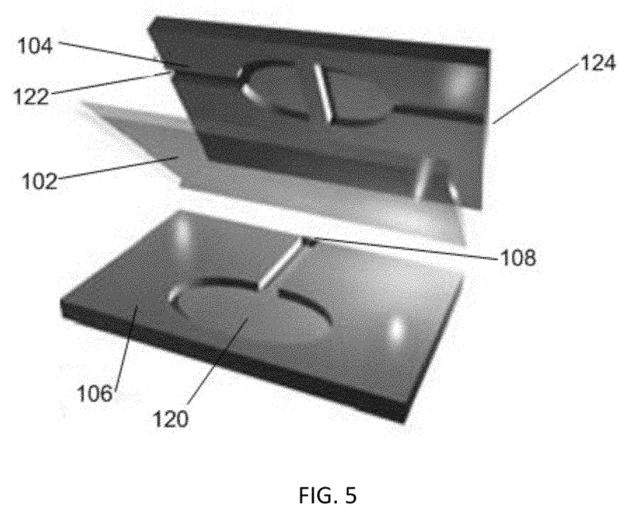

FIGS. 4 and 5 are diagrammatic views of a pneumatic membrane valve (100). As shown, a polydimethylsiloxane (“PDMS”) membrane (102) is sandwiched between two wafers or substrates (104) and (106). When a vacuum is applied to a control channel 108, the membrane (102) is pulled from its valve seat (107) into a displacement chamber (120) to abut against a wall (109) of the displacement chamber. FIG. 4 shows an example of a membrane valve in default position (100) and a membrane valve in deformed position (150) when a vacuum is applied to the control channel (108). In some implementations, the valve seat (107) and the two substrates (104) and (106) are made of glass. As such, fluid is free to flow from an input channel (122) to an output channel (124). The nature of the glass-PDMS bond makes the valve effective for controlling on-chip flows of gas as well.

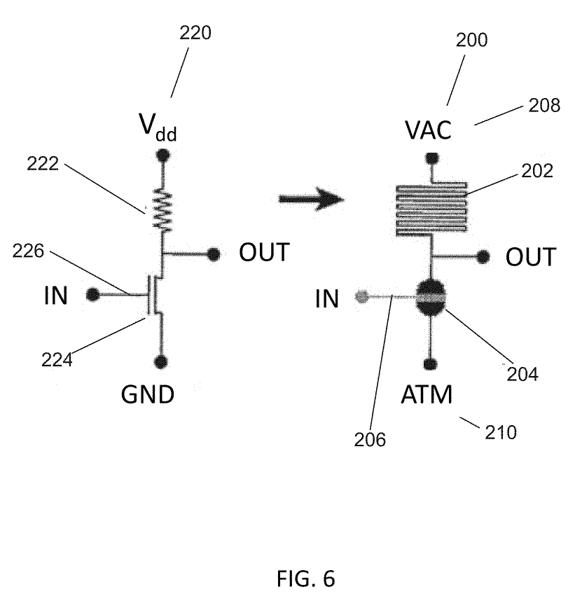

A pneumatic inverter logic gate may utilize such a pneumatic membrane valve that is closed at rest and opened by applying vacuum to the gate input. FIG. 6 is a diagrammatic representation of a pneumatic inverter logic gate (200) and an electronic inverter logic gate (220) using an n-channel field effect transistor (224). The pneumatic inverter logic gate (200) can be thought of analogously to the electronic gate (220), as both are normally-off devices. Pneumatic logic gates and circuits can be constructed by mimicking the n-channel MOSFET (NMOS) logic family of electronics, with transistors (224) replaced by valves (204), wires (226) replaced by channels (206), and electronic pull-up resistors (222) replaced by long, narrow microfluidic channel pull-up resistors (202), wherein the pull-up resistance of the pull-up resistors (202) varies as a function of the length of the long, narrow microfluidic channels comprising the pull-up resistors (202). Instead of being powered by a voltage differential as in electronics, these circuits are powered by a pressure differential. A vacuum line may provide supply vacuum (“VAC”) pressure (208) to the microfluidic chip. In some implementations, the oscillation frequency of the oscillator circuit may vary as a function of the supply vacuum pressure (208). VAC may be defined to be the supply and atmospheric (“ATM”) pressure (210) to be the ground, wherein VAC represents binary 1, and ATM represents binary 0. This maintains the analogy to NMOS logic, since the membrane valves open with an input of 1. All of the fundamental Boolean operations are possible in this technology. In the case of a binary inverter, an input (IN) of 1 opens the valve (204) and pulls down the output (OUT) to 0, whereas an input (IN) of 0 closes the valve, allowing current through the pull-up resistor (202) to bring the output (OUT) to 1.

FIG. 1 provides an exploded diagrammatic representation of the three-inverter oscillator circuit 240, with details regarding the logic gate components that are included in the inverter logic gates (242, 244, 246). Nodes (261, 263, 265) are located between the logic gates (242, 244, 246). As noted in FIG. 1, each logic gate includes a pneumatic valve (204), a pull-up resistor (202), an input, an output, and connections to VAC and ATM. Due to the delay provided by each of the inverter logic gates, the binary values at the nodes oscillate in a coordinated manner and at an oscillation frequency, and the resulting oscillation provides a frequency reference for operations on a microfluidic chip. In some implementations, the oscillation frequency of the circuit is between approximately 2.0 Hz and 5.0 Hz. In other implementations, the oscillation frequency may be less or greater than that specified range. While FIG. 1 depicts a 3-inverter oscillator circuit, it should be noted that any odd number of inverter logic gates may be used to implement an oscillator circuit.

FIG. 3 is a graphical representation 342 of the output values at nodes 1, 2, and 3, and a graphical (344) and diagrammatic (360) representation of the opening and closing of valves A, B, and C as a function of time (345). The output values of nodes 1, 2 and 3 may be one of VAC or ATM, depending on the output of the logic gates, with VAC corresponding to a binary 1 value and ATM corresponding to a binary 0 value. Due to the delay inherent in the logic gates, the square waveforms for the nodes are offset from each other, as are the square waveforms for the opening and closing of valves A, B, and C. The waveform for a fluid valve (e.g., valve A) corresponds to the waveform of the node to which the valve is connected (e.g., node 1). The pumping pattern graph (360) demonstrates how fluid is moved through the valves as the valves open and close in a coordinated manner. The shaded valves (362) represent open valves and the non-shaded valves (364) represent closed valves. As valves A, B, and C open and close in a coordinated oscillatory manner, fluids may be moved through the open valves by the oscillator pump as time progresses.

As used herein, the term “about” refers to plus or minus 10% of the referenced number.

The disclosure of the following U.S. Patents is incorporated in its entirety by reference herein: U.S. Pat. No. 7,445,926.

Various modifications of the invention, in addition to those described herein, will be apparent to those skilled in the art from the foregoing description. Such modifications are also intended to fall within the scope of the appended claims. Each reference cited in the present application is incorporated herein by reference in its entirety.

Although there has been shown and described the preferred embodiment of the present invention, it will be readily apparent to those skilled in the art that modifications may be made thereto which do not exceed the scope of the appended claims. Therefore, the scope of the invention is only to be limited by the following claims. Reference numbers recited in the claims are exemplary and for ease of review by the patent office only, and are not limiting in any way. In some embodiments, the figures presented in this patent application are drawn to scale, including the angles, ratios of dimensions, etc. In some embodiments, the figures are representative only and the claims are not limited by the dimensions of the figures. In some embodiments, descriptions of the inventions described herein using the phrase “comprising” includes embodiments that could be described as “consisting of”, and as such the written description requirement for claiming one or more embodiments of the present invention using the phrase “consisting of” is met.

The reference numbers recited in the below claims are solely for ease of examination of this patent application, and are exemplary, and are not intended in any way to limit the scope of the claims to the particular features having the corresponding reference numbers in the drawings.

What is claimed is:

1. A pump (400) comprising:
(a) a ring oscillator circuit (350) producing a plurality of pressure oscillations for driving a plurality of out-of-phase expansions and contractions of a plurality of valves (302,304,306), arranged in series, to drive a net transport of a gas or liquid, wherein two or more pressure oscillations are phase shifted relative to one another by a value not equal to 180 degrees to create asymmetry, the ring oscillator circuit (350) comprising:
(i) an odd number of three or more pneumatic or hydraulic inverter logic gates (312,314,316), herein referred to as inverter logic gates, wherein an application of higher pressure at an input of an inverter logic gate results in lower pressure at an output of said inverter logic gate, wherein an application of lower pressure at the input of an inverter logic gate results in higher pressure at the output of said inverter logic gate; and
(ii) one or more logic channels (300), wherein the inverter logic gates are arranged in a ring configuration, wherein the output of each inverter logic gate is operatively connected by a logic channel to the input of a next inverter logic gate, wherein the output of a last inverter logic gate is operatively connected to the input of a first inverter logic gate; and
(b) a plurality of fluid channels (330) effective for a coordinated movement of a flow of the gas or liquid;
wherein the plurality of valves (302,304,306) sequentially connects the plurality of fluid channels (330), wherein each valve is operatively connected to the output of one of the inverter logic gates (312,314,316) via a node (322,324,326), wherein each node is disposed at the output of each inverter logic gate.

2. The pump (400) of claim 1, wherein said asymmetric phase shift is 72 degrees.

3. The pump (400) of claim 1, wherein the ring oscillator circuit (350) comprises three inverter logic gates, wherein the pump (400) comprises three valves.

4. The pump (400) of claim 1, wherein the ring oscillator circuit (350) comprises five inverter logic gates, wherein the pump (400) comprises three valves.

5. The pump (400) of claim 1, wherein the pump (400) is configured to mix, meter, recirculate, or agitate the gas or liquid alone or in combination with other gases or liquids.

6. The pump (400) of claim 1, wherein the ring oscillator circuit (350) is treated by a thermal annealing process to improve the stability of an oscillation frequency characterized by said circuit.

8. The pump (400) of claim 1, wherein each pneumatic inverter logic gate is driven by vacuum pressure, via a vacuum supply source, and exhibits a gain greater than 1,
wherein atmospheric pressure is defined as ground, wherein an application of vacuum pressure at the input of a pneumatic inverter logic gate results in atmospheric pressure at the output of said pneumatic inverter logic gate, wherein an application of atmospheric pressure at the input of the pneumatic inverter logic gate results in vacuum pressure at the output of said pneumatic inverter logic gate,
wherein each valve (302,304.306) is configured to be open at an application of vacuum pressure at the output of the pneumatic inverter logic gate to which said valve is connected and closed at an application of atmospheric pressure at the output of the pneumatic inverter logic gate to which said valve is connected.

9. The pump (400) of claim 8, wherein the vacuum supply source is a syringe.

10. The pump (400) of claim 8, wherein each pneumatic inverter logic gate comprises: a pneumatic membrane valve, having a membrane valve control channel, a membrane valve input channel, and a membrane valve output channel,
wherein when vacuum pressure is applied to the membrane valve control channel, the pneumatic membrane valve opens allowing atmospheric pressure to flow from the membrane valve input channel to the membrane valve output channel,
wherein when atmospheric pressure is applied to the membrane valve control channel, the pneumatic membrane valve closes.

11. The pump (400) of claim 10, wherein each pneumatic inverter logic gate further comprises a pull-up resistor channel comprising a long narrow channel separating the vacuum supply source from the output of the pneumatic membrane valve, wherein the pull-up resistor channel has a pull-up resistance that varies as a function of a length of the long narrow channel, wherein the oscillation frequency of he ring oscillator circuit (350) varies as a function of the pull-up resistance.

12. The pump (400) of claim 11, wherein the oscillation frequency of the ring oscillator circuit (350) varies as a function of resistance characteristics of the pull-up resistor channel.

13. A pump comprising:
(a) a ring oscillator circuit producing a plurality of pressure oscillations for driving a plurality of out-of-phase expansions and contractions of a first valve and a second valve, arranged in series, to drive a net transport of a gas or liquid, wherein two or more pressure oscillations are phase shifted relative to one another by a value not equal to 180 degrees to create asymmetry, the ring oscillator circuit comprising:
(i) one pneumatic or hydraulic inverter logic gate herein referred to as an inverter logic gate, wherein an application of higher pressure at an input of the inverter logic gate results in lower pressure at an output of said inverter logic gate, wherein an application of lower pressure at the input of the inverter logic gate results in higher pressure at the output of said inverter logic gate; and
(ii) one or more logic channels operatively connecting the input and the output of the inverter logic gate to form a ring configuration; and
(b) a plurality of fluid channels effective for a coordinated movement of a flow of the gas or liquid;
wherein the first and the second valve sequentially connects the plurality of fluid channels, wherein the first valve is operatively connected to the output of the inverter logic gate via an output node and the second valve is operatively connected to the input of the inverter logic gate via an input node,
wherein a fluidic resistance of the one or more logic channel results in a phase shift between oscillations at the input and output nodes, said oscillations resulting in the plurality of pressure oscillations driving the plurality of out-of-phase expansions and contractions of the first and the second valves.

14. The pump of claim 13, wherein said asymmetric phase shift is 72 degrees.

15. The pump of claim 13, wherein the pump is configured to mix, meter, recirculate, or agitate the gas or liquid alone or in combination with other gases or liquids.

16. The pump of claim 13, wherein the ring oscillator circuit is treated by a thermal annealing process to improve the stability of an oscillation frequency characterized by said circuit.

17. The pump of claim 13, wherein the pneumatic inverter logic gate is driven by vacuum pressure, via a vacuum supply source, and exhibits a gain greater than 1,
wherein atmospheric pressure is defined as ground, wherein an application of vacuum pressure at the input of the pneumatic inverter logic gate results in atmospheric pressure at the output of said pneumatic inverter logic gate, wherein an application of atmospheric pressure at the input of the pneumatic inverter logic gate results in vacuum pressure at the output of the pneumatic inverter logic gate,
wherein the first and the second valves are configured to be open at an application of vacuum pressure at the output of the pneumatic inverter logic gate to which said valve is connected and closed at an application of atmospheric pressure at the output of the pneumatic inverter logic gate to which said valve is connected.

18. The pump of claim 17, wherein the pneumatic inverter logic gate comprises: a pneumatic membrane valve, having a membrane valve control channel, a membrane valve input channel, and a membrane valve output channel,
wherein when vacuum pressure is applied to the membrane valve control channel, the pneumatic membrane valve opens allowing atmospheric pressure to flow from the membrane valve input channel to the membrane valve output channel,
wherein when atmospheric pressure is applied to the membrane valve control channel, the pneumatic membrane valve closes.

19. The pump of claim 18, wherein the pneumatic inverter logic gate further comprises a pull-up resistor channel comprising a long narrow channel separating the vacuum supply source from the output of the pneumatic membrane valve, wherein the pull-up resistor channel has a pull-up resistance that varies as a function of a length of the long narrow channel, wherein the oscillation frequency of the ring oscillator circuit (350) varies as a function of the pull-up resistance.

20. The pump of claim 19, wherein the oscillation frequency of the ring oscillator circuit varies as a function of resistance characteristics of the pull-up resistor channel.
